(19) United States
(12) Patent Application Publication
(10) Pub. No.: US 2022/0181363 A1
(43) Pub. Date: Jun. 9, 2022

(54) SENSOR CHIP AND DISTANCE MEASUREMENT DEVICE

(71) Applicant: SONY SEMICONDUCTOR SOLUTIONS CORPORATION, KANAGAWA (JP)

(72) Inventors: AKIRA MATSUMOTO, KANAGAWA (JP); YOSHIAKI KITANO, KANAGAWA (JP); YUSUKE TAKATSUKA, KANAGAWA (JP)

(21) Appl. No.: 17/441,542

(22) PCT Filed: Feb. 21, 2021
(86) PCT No.: PCT/JP2020/007046

§ 371 Date: Sep. 21, 2021

(30) Foreign Application Priority Data
Mar. 29, 2019 (JP) 2019-065375

(51) Int. Cl. H01L 27/146; H01L 31/107

(52) U.S. Cl. CPC H01L 27/1463; H01L 31/107; H01L 27/14643

(57) ABSTRACT

A sensor chip of an embodiment of the present disclosure includes: a semiconductor substrate including a pixel array section in which a plurality of pixels is arranged in an array; a light receiving element provided in the semiconductor substrate for each of the pixels and including a multiplier region in which avalanche multiplication of carriers is caused by a high electric field region; and a first pixel separation section provided between the pixels, the first pixel separation section extending from one surface of the semiconductor substrate toward another surface thereof opposed to the one surface, and having a bottom in the semiconductor substrate.

### TECHNICAL FIELD

The present disclosure relates to a sensor chip using, for example, an avalanche photodiode, and a distance measurement device including the sensor chip.

### BACKGROUND ART

In a distance measurement image sensor (a distance measurement device) that uses a single photon avalanche diode (SPAD), light emission in a high electric field region in a pixel at the time of multiplication of carriers can cause a photon to enter an adjacent pixel, thereby causing a signal to be unintentionally detected in the adjacent pixel. To cope with this, for example, PLT 1 discloses a sensor chip in which an inter-pixel separation section that physically separates a pixel from another adjacent pixel is provided in a semiconductor substrate in which an avalanche photodiode element is formed.

### CITATION LIST

### Patent Literature

PTL 1: Japanese Unexamined Patent Application Publication No. 2018-88488

### SUMMARY OF THE INVENTION

Meanwhile, a reduction in pixel size is demanded of a sensor chip that configures a distance measurement device.

It is desirable to provide a sensor chip and a distance measurement device that make it possible to reduce the pixel size.

A sensor chip of an embodiment of the present disclosure includes: a semiconductor substrate including a pixel array section in which a plurality of pixels is arranged in an array; a light receiving element provided in the semiconductor substrate for each pixel and including a multiplier region in which avalanche multiplication of carriers is caused by a high electric field region; and a first pixel separation section provided between the pixels, the first pixel separation section extending from one surface of the semiconductor substrate toward another surface thereof opposed to the one surface, and having a bottom in the semiconductor substrate.

A distance measurement device of an embodiment of the present disclosure includes an optical system, a sensor chip, and a signal processing circuit that calculates a distance to a measurement target object from an output signal of the sensor chip. The distance measurement device includes, as the sensor chip, the above-described sensor chip of the embodiment of the disclosure.

According to the sensor chip and the distance measurement device of the respective embodiments of the disclosure, in the pixel array section of the semiconductor substrate in which the plurality of pixels is arranged in an array, the first pixel separation section extending from one surface toward the other surface between the pixels has the bottom provided in the semiconductor substrate. The semiconductor substrate is thereby shared on side of the other surface in the pixel array section.

### BRIEF DESCRIPTION OF THE DRAWINGS

FIG. 1 is a schematic cross-sectional diagram illustrating an example of an outline configuration of a sensor chip according to an embodiment of the present disclosure.

FIG. 2 is a schematic planar diagram illustrating an example of a configuration of a pixel array section of the sensor chip illustrated in FIG. 1.

FIG. 3 is a block diagram illustrating an example of a configuration of the sensor chip illustrated in FIG. 1.

FIG. 4 is an example equivalent circuit diagram of a pixel of the sensor chip illustrated in FIG. 1.

FIG. 5 is a schematic diagram describing a structure of a pixel separation section of the sensor chip illustrated in FIG. 1.

FIG. 6 is a schematic cross-sectional diagram illustrating an example of an outline configuration of a sensor chip as a reference example.

FIG. 7 is a schematic cross-sectional diagram describing an effect of the sensor chip illustrated in FIG. 1.

FIG. 8 is a schematic cross-sectional diagram illustrating an example of an outline configuration of a sensor chip according to Modification Example 1 of the present

FIG. 9 is a schematic cross-sectional diagram illustrating an example of the outline configuration of the sensor chip according to Modification Example 1 of the present disclosure.

FIG. 10A is a schematic plan view of the sensor chip taken along line I-I′ illustrated in FIGS. 8 and 9.

FIG. 10B is a schematic plan view of the sensor chip taken along line II-II′ illustrated in FIGS. 8 and 9.

FIG. 11 is a schematic cross-sectional diagram illustrating another example of the outline configuration of the sensor chip according to Modification Example 1 of the present disclosure.

FIG. 12 is a schematic cross-sectional diagram illustrating another example of the outline configuration of the sensor chip according to Modification Example 1 of the present disclosure.

FIG. 13 is a schematic cross-sectional diagram illustrating an example of an outline configuration of a sensor chip according to Modification Example 2 of the present disclosure.

FIG. 14 is a schematic cross-sectional diagram illustrating an example of an outline configuration of a sensor chip according to Modification Example 3 of the present disclosure.

FIG. 15 is a block diagram depicting an example of schematic configuration of a vehicle control system.

FIG. 16 is a diagram of assistance in explaining an example of installation positions of an outside-vehicle information detecting section and an imaging section.

### MODES FOR CARRYING OUT THE INVENTION

In the following, an embodiment of the present disclosure will be described in detail with reference to the drawings. The following description is a specific example of the present disclosure, and the present disclosure is not limited to the following embodiment. Further, the present disclosure does not limit the disposition, dimensions, dimension ratios, and the like of components illustrated in the drawings thereto. It is to be noted that the description is given in the following order.

1. Embodiment (an example of a sensor chip in which a p-well is shared by pixels on side of a light receiving surface)

1-1. Configuration of Sensor Chip

1-2. Method of Manufacturing Sensor Chip

1-3. Operation of Sensor Chip

1-4. Workings and Effects

### 2. Modification Examples

2-1. Modification Example 1 (an example in which a pixel separation section is further provided on side of a light entrance surface)

2-2. Modification Example 2 (an example in which a wiring line is coupled to the pixel separation section)

2-3. Modification Example 3 (an example in which a semiconductor substrate and an inter-pixel light-blocking film are electrically coupled to each other in a peripheral section)

### 3. Example of Application

### 1. Embodiment

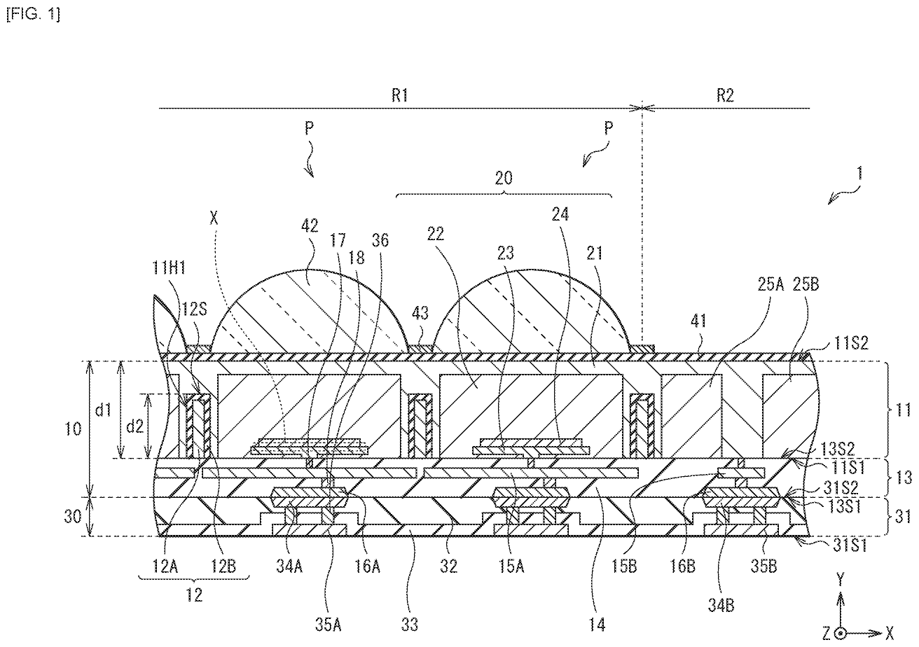

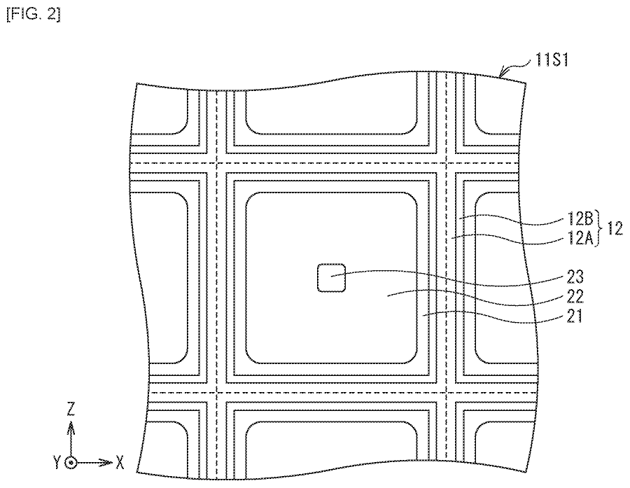

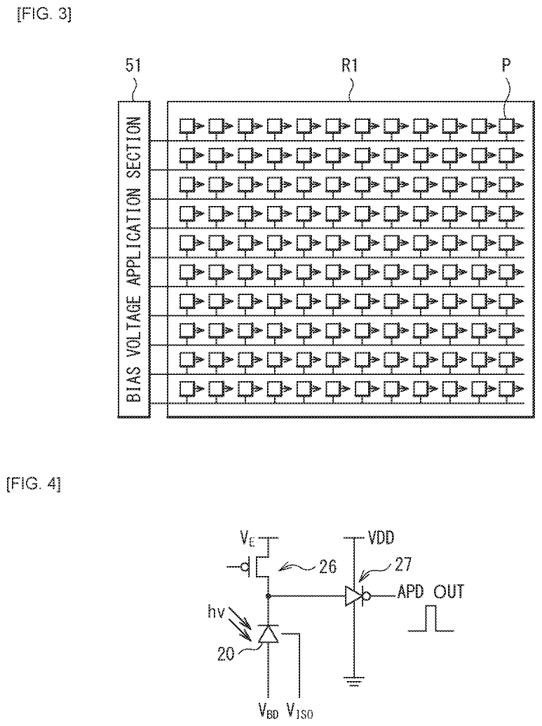

FIG. 1 schematically illustrates an example of a cross-sectional configuration of a sensor chip (a sensor chip 1) according to an embodiment of the present disclosure. FIG. 2 schematically illustrates an example of a planar configuration of a pixel array section R1 of the sensor chip 1 illustrated in FIG. 1. FIG. 3 is a block diagram illustrating a configuration of the sensor chip 1 illustrated in FIG. 1, and FIG. 4 illustrates an example of an equivalent circuit of a pixel P of the sensor chip 1 illustrated in FIG. 1. The sensor chip 1 is configured to be applied to, for example, a distance image sensor (a distance measurement device), an image sensor, or the like that performs distance measurements by a ToF (Time-of-Flight) method.

The sensor chip 1 includes, for example, the pixel array section R1 in which a plurality of pixels P is arranged in an array, and a peripheral section R2 provided around the pixel array section R1. The plurality of pixels P each includes, for example, a light receiving element 20, a p-type MOSFET (Metal-Oxide-Semiconductor Field-Effect Transistor) 26, and a CMOS inverter 27. Further, the sensor chip 1 has a structure in which a sensor substrate 10 and a logic substrate 30 are stacked on each other, for example. The sensor substrate 10 has a stacked structure including a semiconductor substrate 11 provided with the light receiving element 20, and a wiring layer 13 provided on side of a front surface (a surface 11S1) of the semiconductor substrate 11. The logic substrate 30 is stacked on the wiring layer 13 (on side of a surface 13S1 of the wiring layer 13). The sensor chip 1 of the present embodiment has a structure in which a pixel separation section 12 extending from the surface 11S1 of the semiconductor substrate 11 toward a back surface opposed thereto (a surface 11S2, a light receiving surface) and having a bottom 12S in the semiconductor substrate 11 is provided between the pixels. The pixel separation section 12 corresponds to a specific example of a “first pixel separation section” of the present disclosure.

### 1-1. Configuration of Sensor Chip

The sensor chip 1 is, for example, a so-called back illumination type sensor chip in which the logic substrate 30 is stacked on side of a front surface of the sensor substrate 10 (e.g., side of the front surface (the surface 11S1) of the semiconductor substrate 11) and light is received from side of a back surface thereof (e.g., side of the back surface (the surface 11S2) of the semiconductor substrate 11).

The sensor substrate 10 includes, for example, the semiconductor substrate 11 including a silicon substrate, and the wiring layer 13. The semiconductor substrate 11 of the present embodiment includes a p-well 21 shared by the plurality of pixels P on the back surface (the surface 11S2, the light receiving surface). In the semiconductor substrate 11, a p-type or n-type impurity concentration is controlled for each pixel P, for example, and the light receiving element 20 is thereby formed for each pixel P. Furthermore, as described above, the semiconductor substrate 11 is provided with the pixel separation section 12 extending from the front surface (the surface 11S1) of the semiconductor substrate 11 toward the back surface (the surface 11S2) thereof. The pixel separation section 12 has the bottom 12S in the semiconductor substrate 11, and the p-well 21 is thus shared by the plurality of pixels P. The wiring layer 13 is provided on side of the front surface (the surface 11S1) of the semiconductor substrate 11.

The light receiving element 20 includes a multiplier region (an avalanche multiplier region) in which avalanche multiplication of carriers is caused by a high electric field region. The light receiving element 20 is an SPAD element that is able to form an avalanche multiplier region upon application of a large negative voltage to an anode, and to perform avalanche multiplication of electrons generated by entry of a single photon.

The light receiving element 20 includes, for example, an n-type semiconductor region 22, an n-type diffusion region 23, and a p-type diffusion region 24 that are formed in the semiconductor substrate 11. In the light receiving element 20, the avalanche multiplier region X is formed by a depletion layer that is formed in a region in which the n-type diffusion region 23 and the p-type diffusion region 24 are coupled to each other.

The n-type semiconductor region 22 is a region in which the impurity concentration of the semiconductor substrate 11 is controlled to be n-type. The n-type semiconductor region 22 is provided in a portion of the front surface (the surface 11S1) of the semiconductor substrate and in the vicinity thereof. In the n-type semiconductor region 22, an electric field is formed that transfers electrons generated by photoelectric conversion in the light receiving element 20 to the avalanche multiplier region X.

The n-type diffusion region 23 is an n-type semiconductor region (n⁺) that is formed in the vicinity of the front surface (the surface 11S1) of the semiconductor substrate 11 in the n-type semiconductor region 22 and has an impurity concentration higher than that of the n-type semiconductor region 22. The n-type diffusion region 23 is formed to extend substantially all over the pixel P. Further, a portion of the n-type diffusion region 23 is in the shape of a projection facing the front surface (the surface 11S1) of the semiconductor substrate 11 in order to be electrically coupled to a contact electrode 17 (cathode).

The p-type diffusion region 24 is a p-type semiconductor region (p⁺) that is formed in the vicinity of the front surface (the surface 11S1) of the semiconductor substrate 11 in the n-type semiconductor region 22, and is formed on side of the light receiving surface (the surface 11S2) relative to the n-type diffusion region 23. Similarly to the n-type diffusion region 23, the p-type diffusion region 24 is formed to extend substantially all over the pixel P.

The avalanche multiplier region X is a high electric field region formed in an interface between the n-type diffusion region 23 and the p-type diffusion region 24 by a large negative voltage applied to an anode (in the present embodiment, the contact electrode 17 coupled to the p-well in the peripheral section R2). In the avalanche multiplier region X, electrons (e⁻) generated by a single photon entering the light receiving element 20 are multiplied.

The pixel separation section 12 is provided between the pixels on the front surface (the surface 11S1) of the semiconductor substrate 11 and serves to electrically and optically separate adjacent pixels P from each other on side of the front surface (the surface 11S1) of the semiconductor substrate 11. The pixel separation section 12 is formed by filling a separation groove 11H1 that extends in a thickness direction (a Y-axis direction) of the semiconductor substrate 11 in the p-well 21 between the pixels with, for example, a light-blocking film 12A and an insulating film 12B. In other words, the pixel separation section 12 includes the light-blocking film 12A and the insulating film 12B, and the insulating film 12B is provided to cover a surface (a side surface and a bottom surface) of the light-blocking film 12A. The light-blocking film 12A corresponds to a specific example of a “first light-blocking film” of the present disclosure.

The separation groove 11H1 is formed from the front surface (the surface 11S1) of the semiconductor substrate 11 toward the back surface (the surface 11S2) thereof, and the semiconductor substrate 11 including the p-well 21 remains on a bottom thereof. That is, a depth (d2) of the separation groove 11H1 is smaller than or equal to a thickness (d1) of the semiconductor substrate 11. As a result, the p-well 21 is shared by the plurality of pixels P.

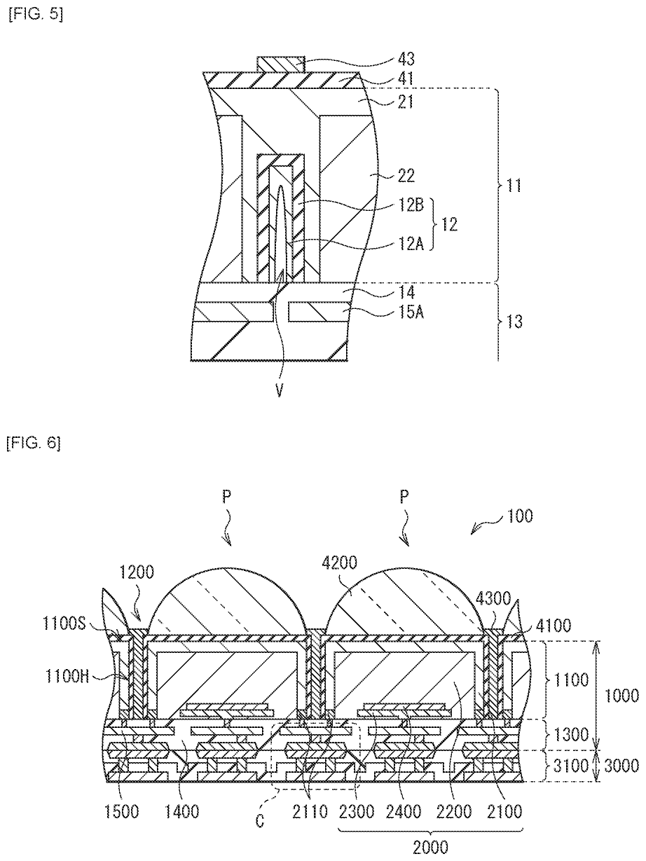

The light-blocking film 12A includes an electrically-conductive material having a light-blocking property. Examples of such a material include tungsten (W), silver (Ag), copper (Cu), aluminum (Al), an alloy of Al and copper (Cu), and the like. It is to be noted that, as illustrated in FIG. 5, for example, a void V may be formed inside the light-blocking film 12A. The insulating film 12B includes silicon oxide (SiOₓ) or the like, for example.

The semiconductor substrate 11 is further provided with n-type semiconductor regions 25A and 25B with the p-well 21 interposed therebetween in the peripheral section R2, for example.

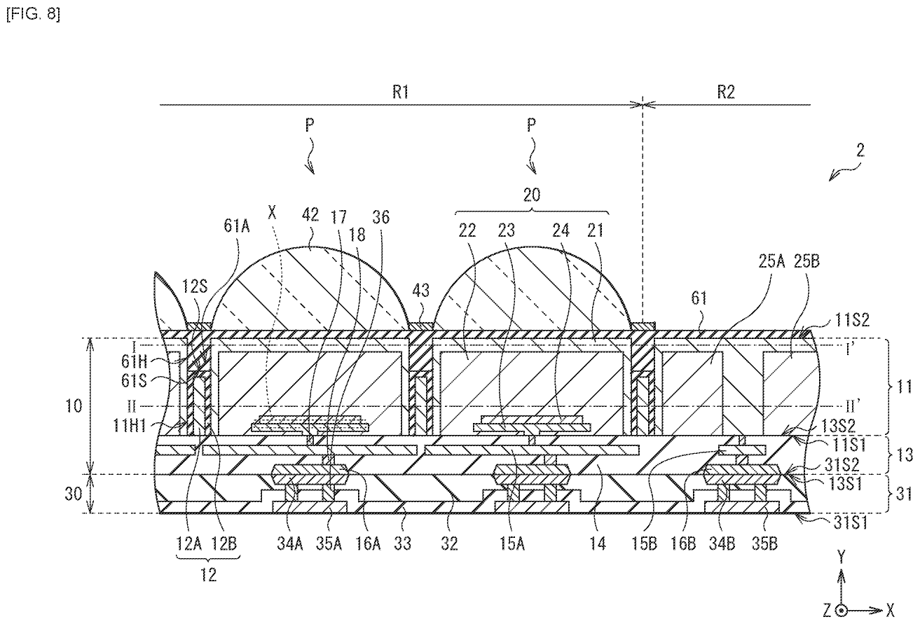

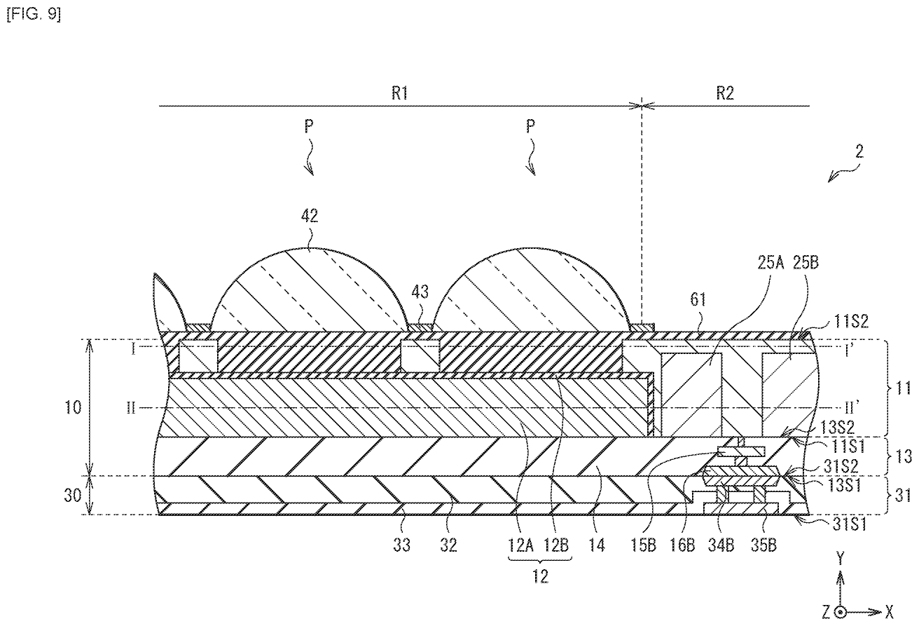

The wiring layer 13 is provided in contact with the front surface (the surface 11S1) of the semiconductor substrate 11, and includes, for example, an interlayer insulating film 14, wiring lines 15A and 15B, and pad sections 16A and 16B. The wiring lines 15A and 15B and the pad sections 16A and 16B are for supplying a voltage to be applied to the p-well 21 and the light receiving element 20, and for extracting electric charge (e.g., electron) generated in the light receiving element 20, for example. For example, the wiring line 15A is electrically coupled to the n-type diffusion region 23 via the contact electrode 17, and the pad section 16A is electrically coupled to the wiring line 15A via a contact electrode 18. The wiring line 15B is electrically coupled to the p-well 21 via the contact electrode 17 in the peripheral section R2, and the pad section 16B is electrically coupled to the wiring line 15B via the contact electrode 18. It is to be noted that while FIG. 1 illustrates an example in which single-layer wiring lines (the wiring lines 15A and 15B) are formed in the wiring layer 13, the total number of the wiring lines in the wiring layer 13 is not limited, and wiring lines including two or more layers may be formed. Hereinafter, the same applies to Modification Examples 1 to 3 (FIGS. 8, 9, and 11 to 14).

The interlayer insulating film 14 includes, for example, a single-layer film including one of silicon oxide (SiOₓ), TEOS, silicon nitride (SiNₓ), silicon oxynitride (SiOₓN_{y}), and the like, or a stacked film including two or more of them.

The wiring lines 15A and 15B are formed in the interlayer insulating film 14. The wiring line 15A is formed over a wider range than the avalanche multiplier region X so as to cover the avalanche multiplier region X, for example, and also serves as a reflector that reflects light transmitted through the light receiving element 20 to the light receiving element 20. The wiring line 15A corresponds to a specific example of a “light reflection section” of the present disclosure. The wiring line 15B is electrically coupled to the p-well 21 with the contact electrode 17 as the anode in the peripheral section R2, for example. The wiring lines 15A and 15B include, for example, aluminum (Al), copper (Cu), tungsten (W), or the like.

The pad sections 16A and 16B are exposed in a bonding surface of the interlayer insulating film 14 (for example, the surface 13S1 of the wiring layer 13) to the logic substrate 30, and are used for coupling to the logic substrate 30, for example. The pad sections 16A and 16B include copper (Cu) pads, for example

The logic substrate 30 includes a wiring layer 31 in contact with a bonding surface of the sensor substrate 10 (e.g., the surface 13S1 of the wiring layer 13), and a semiconductor substrate (not illustrated) in which a bias voltage application section 51 (see FIG. 3), and the p-type MOSFET 26 and the CMOS inverter 27 constituting the pixel P are formed and which is opposed to the sensor substrate 10. The wiring layer 31 includes an interlayer insulating film 32, an insulating film 33, pad sections 34A and 34B, and pad electrodes 35A and 35B.

The wiring layer 31 includes the interlayer insulating film 32 and the insulating film 33 in this order from side of the sensor substrate 10. The interlayer insulating film 32 and the insulating film 33 are provided to be stacked on each other. Similarly to the interlayer insulating film 14, the interlayer insulating film 32 and the insulating film 33 include, for example, a single-layer film including one of silicon oxide (SiOₓ), TEOS, silicon nitride (SiNₓ), silicon oxynitride (SiOₓN_{y}), and the like, or a stacked film including two or more of them.

The pad sections 34A and 34B are exposed in a bonding surface of the interlayer insulating film 32 (for example, a surface 3152 of the wiring layer 31) to the sensor substrate 10, and are used for coupling to the sensor substrate 10, for example. The pad sections 34A and 34B include copper (Cu) pads, for example. The pad electrodes 35A and 35B are used for coupling to the semiconductor substrate of the logic substrate 30, for example, and include aluminum (Al), copper (Cu), tungsten (W), or the like, for example. The pad sections 34A and 34B and the pad electrodes 35A and 35B are for supplying a voltage to be applied to the p-well 21 and the light receiving element 20 from the bias voltage application section 51, and for extracting electric charge (e.g., electron) generated in the light receiving element 20, for example. For example, the pad sections 34A and 34B are electrically coupled to the pad electrodes 35A and 35B, respectively, via a contact electrode 36.

In the sensor chip 1, for example, Cu—Cu bonding is established between the pad sections 16A and 16B and the pad sections 34A and 34B. As a result, for example, the pad electrode 35A in the pixel array section R1 is electrically coupled to the n-type diffusion region 23, for example, via the contact electrode 36, the pad section 34A, the pad section 16A, the contact electrode 18, the wiring line 15A, and the contact electrode 17. Further, the pad electrode 35B in the peripheral section R2 is electrically coupled to the p-well 21, for example, via the contact electrode 36, the pad section 34B, the pad section 16B, the contact electrode 18, the wiring line 15B, and the contact electrode 17.

The bias voltage application section 51 applies a vias voltage to each of a plurality of light receiving elements 20 disposed for individual pixels P in the pixel array section R1. When the voltage resulting from the electrons avalanche-multiplied in the light receiving element 20 reaches a negative voltage (V_{BD}), the p-type MOSFET 26 performs quenching to discharge the electrons avalanche-multiplied in the light receiving element 20 to thereby recover an initial voltage. The CMOS inverter 27 shapes a voltage generated by the electrons avalanche-multiplied in the light receiving element 20 to thereby output a light receiving signal (APD OUT) generated by a pulse waveform with an arrival time of a single photon as a point of view.

For example, an on-chip lens 42 is provided on side of the light receiving surface of the sensor substrate 10 (the back surface (the surface 11S2) of the semiconductor substrate 11) with a passivation film 41 interposed therebetween for each pixel P, for example. Further, an inter-pixel light-blocking film 43 is provided between the pixels.

The passivation film 41 is for protecting the back surface (the surface 11S2) of the semiconductor substrate 11. Further, the passivation film 41 may have an antireflection function, for example. The passivation film 41 includes a silicon nitride (SiN) film, an aluminum oxide (AlOₓ) film, a silicon oxide (SiOₓ) film, a tantalum oxide (TaOₓ) film, or an oxide film including hafnium oxide (HfOₓ), titanium oxide (TiOₓ), or STO.

The on-chip lens 42 is for causing light entering from above to condense onto the light receiving element 20, and includes silicon oxide (SiOₓ) or the like, for example. The inter-pixel light-blocking film 43 is for suppressing crosstalk of obliquely entering light between adjacent pixels. The inter-pixel light-blocking film 43 is provided between adjacent pixels P in the pixel array section R1, for example, and has a grid shape, for example. The inter-pixel light-blocking film 43 includes an electrically-conductive material having a light-blocking property, similarly to the light-blocking film 12A. Specifically, the inter-pixel light-blocking film 43 includes tungsten (W), silver (Ag), copper (Cu), aluminum (Al), an alloy of Al and copper (Cu), or the like.

The sensor chip 1 includes the pixel array section R1, and the peripheral section R2 provided around the pixel array section R1, as described above. In the pixel array section R1, the plurality of pixels P is arranged in an array, and each pixel P is provided with the light receiving element 20, the p-type MOSFET 26, the CMOS inverter 27, etc. described above. In the peripheral section R2, the n-type semiconductor regions 25A and 25B are provided with the p-well 21 interposed therebetween, for example. The wiring line 15B, the pad sections 16B and 34B, and the pad electrode 35B are coupled in order to the p-well 21 between the n-type semiconductor region 25A and the n-type semiconductor region 25B via the contact electrodes 17, 18, and 36, for example. The pad electrode 35B is coupled to a ground (GND), for example.

### 1-2. Method of Manufacturing Sensor Chip

It is possible to manufacture the sensor chip 1 in the following manner, for example. First, the p-type or n-type impurity concentration of the semiconductor substrate 11 is controlled by ion implantation to thereby form the p-well 21, the n-type semiconductor region 22, the n-type diffusion region 23, and the p-type diffusion region 24. Subsequently, patterning is performed on the front surface (the surface 11S1) of the semiconductor substrate 11 with, for example, an oxide film such as SiOₓ or a nitride film as a hard mask, following which the separation groove 11H1 is formed from side of the front surface (the surface 11S1) by etching. Subsequently, the insulating film 12B and the light-blocking film 12A are formed in order on the side surface and the bottom surface of the separation groove 11H1 by, for example, a CVD (Chemical Vapor Deposition) method, a PVD (Physical Vapor Deposition) method, an ALD (Atomic Layer Deposition) method, a vapor deposition method, or the like. Next, the light-blocking film 12A and the insulating film 12B on the front surface (the surface 11S1) of the semiconductor substrate 11 are removed by, for example, CMP (Chemical Mechanical Polishing) with the hard mask as a stopper, following which the wiring layer 13 is formed on the front surface (the surface 11S1) of the semiconductor substrate 11. Thereafter, the logic substrate 30 formed separately is attached thereto. At this time, the pad sections 16A and 16B exposed in a bonding surface 14S1 of the wiring layer 13 and the pad sections 34A and 34B exposed in a bonding surface 32S1 of the wiring layer 31 on side of the logic substrate 30 are bonded to each other by Cu—Cu bonding. Subsequently, the back surface (the surface 11S2) of the semiconductor substrate 11 is polished by, for example, CMP, following which the passivation film 41, the inter-pixel light-blocking film 43, and the on-chip lens 42 are formed in order. The sensor chip 1 illustrated in FIG. 1 is thereby completed.

### 1-3. Operation of Sensor Chip

In the light receiving element 20, when a large negative voltage (V_{BD}) is applied to the anode (the contact electrode 17 coupled to the p-well in the peripheral section R2), the depletion layer spreads from a pn junction surface between the n-type diffusion region 23 and the p-type diffusion region 24 coupled thereto, and the avalanche multiplier region X is thereby formed. In the avalanche multiplier region X, it is possible to perform avalanche multiplication of electrons generated by entry of a single photon. The avalanche-multiplied electrons are extracted as signal electric charge, and subjected to signal processing by a signal processing circuit.

The sensor chip 1 is usable as a distance measurement sensor by the ToF method. In the ToF method, a signal delay time between a signal resulting from the signal electric charge and a reference signal is converted into a distance to a measurement target object. The signal processing circuit calculates the signal delay time from the signal resulting from the signal electric charge obtained from, for example, each pixel P, and the reference signal. The obtained signal delay time is converted into a distance. The distance to the measurement target object is thereby measured.

### 1-4. Workings and Effects

In the sensor chip 1 of the present embodiment, the pixel separation section 12 extending in the semiconductor substrate 11 from the front surface (the surface 11S1) toward the back surface (the surface 11S2) and having the bottom 12S in the semiconductor substrate 11 is provided between the pixels in the pixel array section R1 in which the plurality of pixels P is arranged in an array, and the p-well 21 formed in the semiconductor substrate 11 is thereby shared by the plurality of pixels. This makes it unnecessary to provide an anode for each pixel P, thus making it possible for the anode to be shared by the plurality of pixels. This will be described in the following.

FIG. 6 schematically illustrates a cross-sectional configuration of a typical sensor chip 100 as a reference example. In the typical sensor chip including an avalanche photodiode element for each pixel P, as described above, the inter-pixel separation section that physically separates a pixel from another adjacent pixel is provided in order to prevent color mixture resulting from hot-carrier light emission between adjacent pixels. The pixel separation section penetrates a semiconductor substrate 1100 like the pixel separation section 1200 illustrated in FIG. 6, and the semiconductor substrate 1100 is separated into pieces for individual pixels P. Accordingly, in the sensor chip 100, it is necessary to provide an anode 2410, wiring lines to be coupled thereto, etc. for each pixel P.

In the sensor chip having the above-described configuration, it is necessary to secure a region in which the anode is to be formed in the pixel P, and this makes it difficult to reduce a pixel size.

In contrast, in the present embodiment, the bottom 12S of the pixel separation section 12 is provided in the semiconductor substrate 11, and the p-well 21 formed in the semiconductor substrate 11 is shared by the plurality of pixels P on side of the back surface (the surface 11S2) of the semiconductor substrate 11. This makes it unnecessary to form an anode for each pixel P, thus making it possible to reduce the pixel size by the size of the anode formation region described above.

Alternatively, in a case where the pixel size is maintained, it is possible to increase an area of the n-type diffusion region 23 and the p-type diffusion region 24 by the size of the anode formation region. As a result, it is possible to increase the size of the avalanche multiplier region X. Further, because it is not necessary to provide a wiring structure C to be coupled to an anode 2110 as in the sensor chip 100 illustrated in FIG. 6, it is possible for the reflector (the wiring line 15A) that reflects light transmitted through the semiconductor substrate 11 to the light receiving element 20 to be formed into a larger size. Accordingly, it is possible to improve PDE (Photon Detection Efficiency).

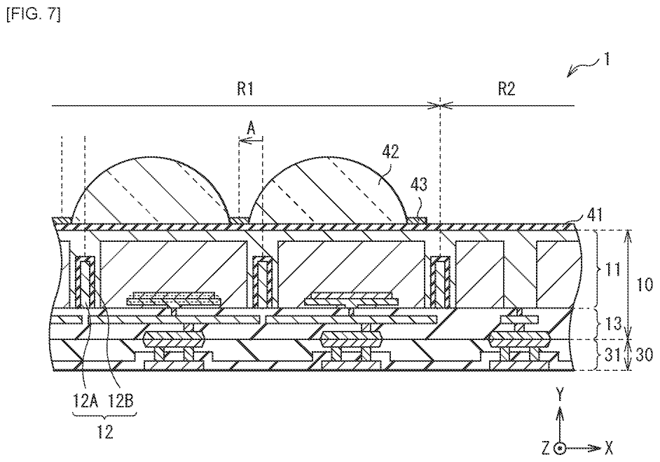

Further, in the typical sensor chip 100, as illustrated in FIG. 6, the pixel separation section 1200 and an inter-pixel light-blocking film 4300 provided between pixels on side of the light receiving surface (a surface 1100S) of the semiconductor substrate 1100 are integrated with each other. In contrast, in the sensor chip 1 of the present embodiment, the pixel separation section 12 and the inter-pixel light-blocking film 43 are formed independently of each other. Therefore, it is possible to easily shift the on-chip lens 42 and the inter-pixel light-blocking film 43 with respect to the pixel P as indicated by an arrow A illustrated in FIG. 7. That is, the degree of design flexibility of the on-chip lens 42 and the inter-pixel light-blocking film 43 with respect to the pixel P improves. Accordingly, it is possible to easily perform pupil correction.

Next, modification examples of the present disclosure will be described. In the following, components similar to those of the embodiment described above are denoted by the same reference numerals, and a description thereof is omitted where appropriate.

### 2. Modification Examples

### 2-1. Modification Example 1

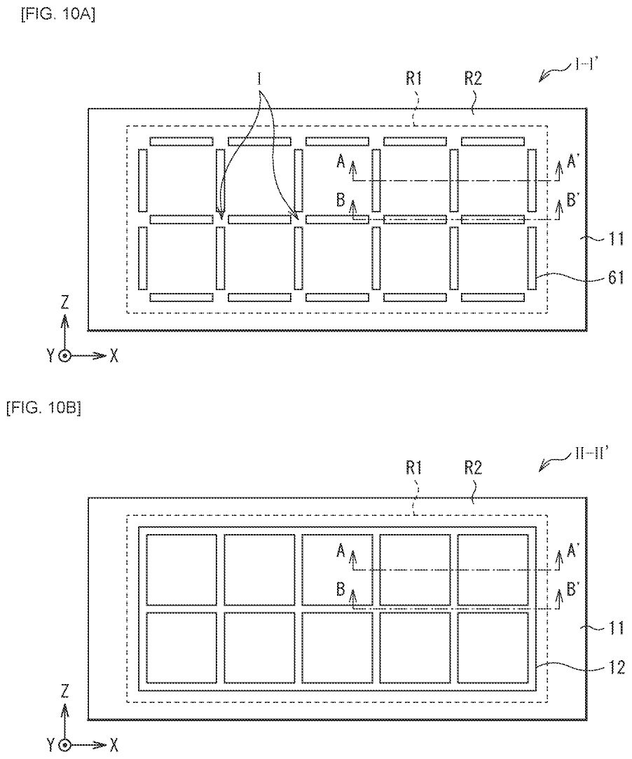

FIG. 8 schematically illustrates an example of a cross-sectional configuration of a sensor chip (a sensor chip 2) according to Modification Example 1 of the present disclosure. FIG. 9 schematically illustrates an example of a cross-sectional configuration at another position in the sensor chip 2. FIG. 10A schematically illustrates a planar configuration taken along line I-I′ illustrated in FIGS. 8 and 9, and FIG. 10B schematically illustrates a planar configuration taken along line II-II′ illustrated in FIGS. 8 and 9. It is to be noted that FIG. 8 illustrates a cross section taken along line A-A′ illustrated in FIGS. 10A and 10B, and FIG. 9 illustrates a cross section taken along line B-B′ illustrated in FIGS. 10A and 10B. Similarly to the sensor chip 1 of the foregoing embodiment, the sensor chip 2 is configured to be applied to, for example, a distance image sensor (a distance measurement device) that performs distance measurements by the ToF method. The sensor chip 2 of the present modification example is different from the foregoing embodiment in that a pixel separation section 61A extending from the back surface (the surface 11S2) of the semiconductor substrate 11 toward the front surface (the surface 11S1) opposed thereto is provided between the pixels. The pixel separation section 61A corresponds to a specific example of a “second pixel separation section” of the present disclosure.

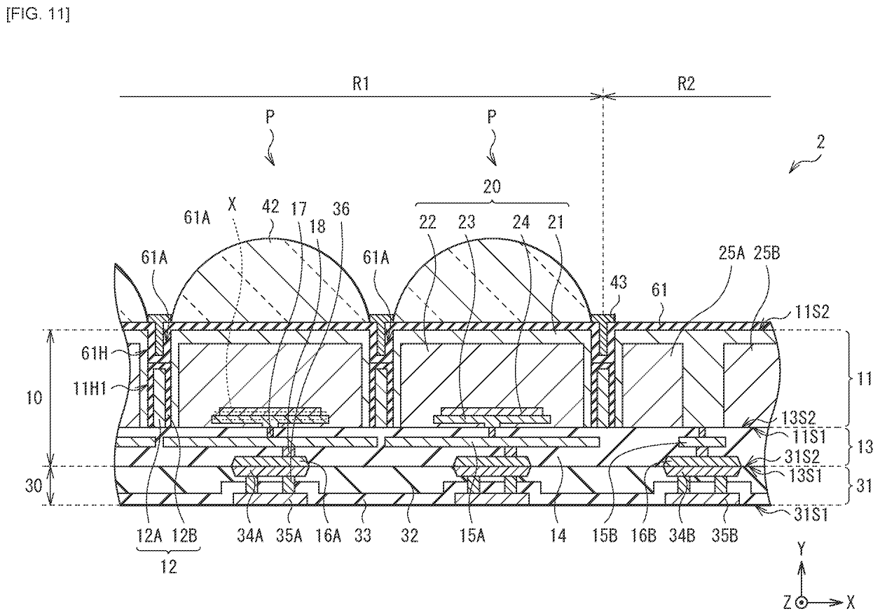

The pixel separation section 61A is for electrically separating adjacent pixels P from each other on side of the back surface (the surface 11S2) of the semiconductor substrate 11. The pixel separation section 61A is formed by filling a separation groove 11H2 extending in the thickness direction (the Y-axis direction) from the back surface (the surface 11S2) of the semiconductor substrate 11 with a passivation film 61 that protects the back surface (the surface 11S2) of the semiconductor substrate 11. The passivation film 61 may have the antireflection function, for example, similarly to the foregoing passivation film 41. The passivation film 61 includes, for example, a silicon nitride (SiN) film or an oxide film such as an aluminum oxide (AlOₓ) film, a silicon oxide (SiOₓ) film, or a tantalum oxide (TaOₓ) film. It is to be noted that the pixel separation section 61A may not necessarily have the above-described configuration, and may have a configuration in which an antireflection film is embedded in an oxide film. Specifically, the inter-pixel light-blocking film 43 may be embedded together with an oxide film (see FIG. 11).

As illustrated in FIG. 9, a bottom 61S of the pixel separation section 61A is in contact with the bottom 12S of the pixel separation section 12 that extends in the thickness direction (the Y-axis direction) from the front surface (the surface 11S1) of the semiconductor substrate 11. Further, as illustrated in FIG. 10A, for example, the pixel separation section 61A is provided in the pixel array section R1 arranged in five rows x two columns, for example, excluding an intersection point I between adjacent pixels. As a result, the p-well 21 of the semiconductor substrate 11 is shared by the plurality of pixels P at the intersection point I between adjacent pixels.

As described above, in the present modification example, the pixel separation section 61A extending from the back surface (the surface 11S2) of the semiconductor substrate 11 toward the front surface (the surface 11S1) opposed thereto is provided between the pixels. This improves a light-confining effect on entering light in the pixel P, in addition to providing the effect of the foregoing embodiment.

Further, as illustrated in FIG. 11, the inter-pixel light-blocking film 43 may extend in the pixel separation section 61A. This makes it possible to further improve the light-confining effect on entering light in the pixel P.

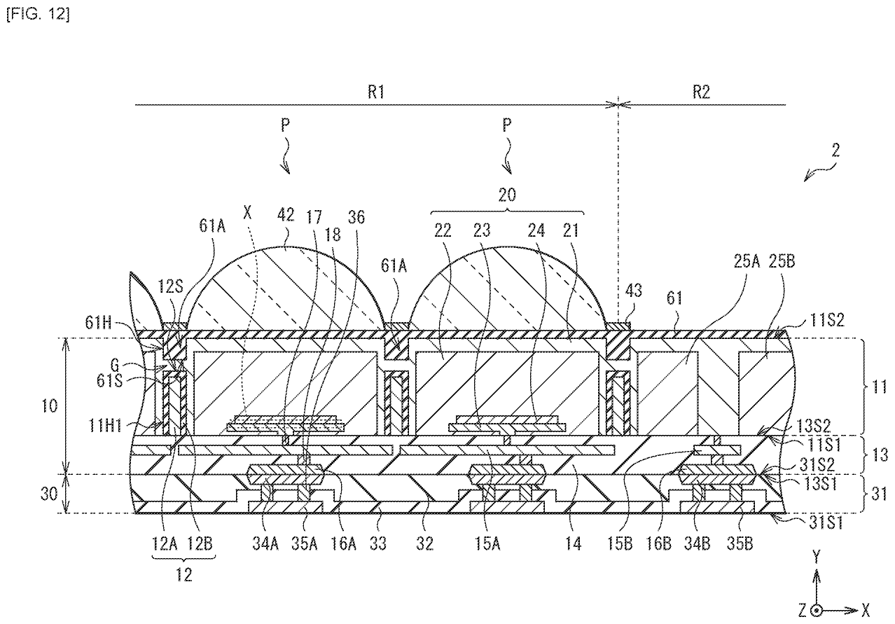

Furthermore, as illustrated in FIG. 12, the pixel separation section 61A may have a gap G between the bottom 61S and the bottom 12S of the pixel separation section 12. In that case, the p-well 21 of the semiconductor substrate 11 is shared by the plurality of pixels P via the gap G, and therefore the pixel separation section 61A may be provided also at the intersection point I between adjacent pixels, similarly to the planar shape of the pixel separation section 12 illustrated in FIG. 10B.

### 2-2. Modification Example 2

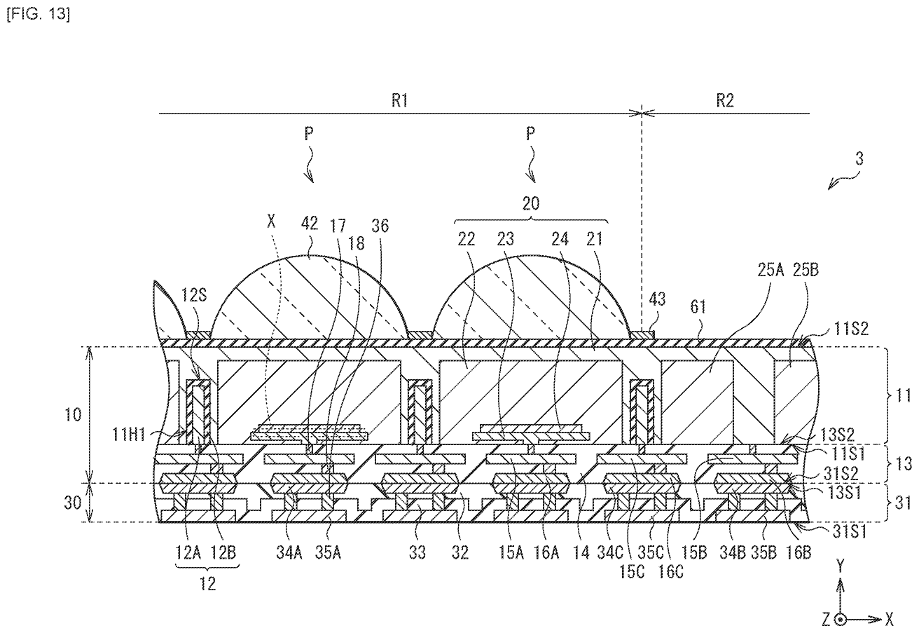

FIG. 13 schematically illustrates an example of a cross-sectional configuration of a sensor chip (a sensor chip 3) according to Modification Example 2 of the present disclosure. Similarly to the sensor chip 1 of the foregoing embodiment, the sensor chip 3 is configured to be applied to, for example, a distance image sensor (a distance measurement device) that performs distance measurements by the ToF method. The sensor chip 3 of the present modification example is different from the foregoing embodiment in that a wiring line is coupled to the pixel separation section 12.

A wiring line 15C, pad sections 16C and 34C, and a pad electrode 35C are electrically coupled to the pixel separation section 12 of the present modification example via the contact electrodes 17, 18, and 36, and it is possible to apply a voltage to the pixel separation section 12 independently of the anode (the contact electrode 17 in the peripheral section R2) and the cathode (the contact electrode 17 in the pixel array section R1). As a result, it is possible to perform pinning to thereby suppress the occurrence of a dark current. Further, it is possible to reduce an electric field to be applied to the insulating film 12B between the light-blocking film 12A and the semiconductor substrate 11 to thereby prevent degradation of the insulating film 12B. Accordingly, it is possible to improve reliability, in addition to providing the effect of the foregoing embodiment.

### 2-3. Modification Example 3

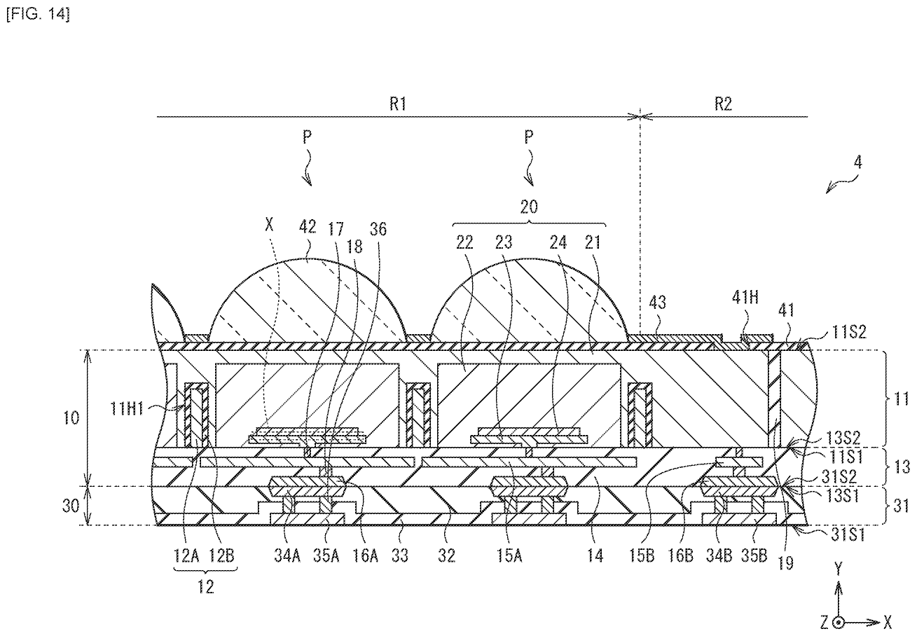

FIG. 14 schematically illustrates an example of a cross-sectional configuration of a sensor chip (a sensor chip 4) according to Modification Example 3 of the present disclosure. Similarly to the sensor chip 1 of the foregoing embodiment, the sensor chip 4 is configured to be applied to, for example, a distance image sensor (a distance measurement device) that performs distance measurements by the ToF method. The sensor chip 4 of the present modification example is different from the foregoing embodiment in that the inter-pixel light-blocking film 43 extends to the peripheral section R2 and the inter-pixel light-blocking film 43 is electrically coupled to the p-well 21 of the semiconductor substrate 11 via an opening 41H provided in the passivation film 41 in the peripheral section R2.

Further, in the sensor chip 4 of the present modification example, as described above, the inter-pixel light-blocking film 43 is electrically coupled to the p-well 21 of the semiconductor substrate 11 in the peripheral section R2. In the peripheral section R2, the contact electrode 17 is coupled as an anode to the p-well 21, and is electrically coupled to the bias voltage application section 51 via the wiring line 15B, the contact electrode 18, the pad sections 16B and 34B, the contact electrode 36, and the pad electrode 35B. This makes it possible to apply an anode potential to also the inter-pixel light-blocking film 43.

Furthermore, in the peripheral section R2, as illustrated in FIG. 14, for example, an insulating film 19 penetrating the semiconductor substrate 11 may be provided to apply potentials that are different between the inside and the outside of the insulating film 19. The outside of the insulating film 19 may be coupled to the ground (GND), for example. This makes it possible to reduce, for example, an influence of application of the potential also to the peripheral section R2 on coupling to a lower substrate (e.g., the logic substrate 30) or the like, which is a matter of concern in the foregoing embodiment.

### 3. Example of Application

### Example of Application to Mobile Body

The technology according to the present disclosure is applicable to various products. For example, the technology according to the present disclosure may be implemented as a device to be mounted on any type of mobile body such as an automobile, an electric vehicle, a hybrid electric vehicle, a motorcycle, a bicycle, a personal mobility, an airplane, a drone, a vessel, a robot, a construction machine, and an agricultural machine (tractor).

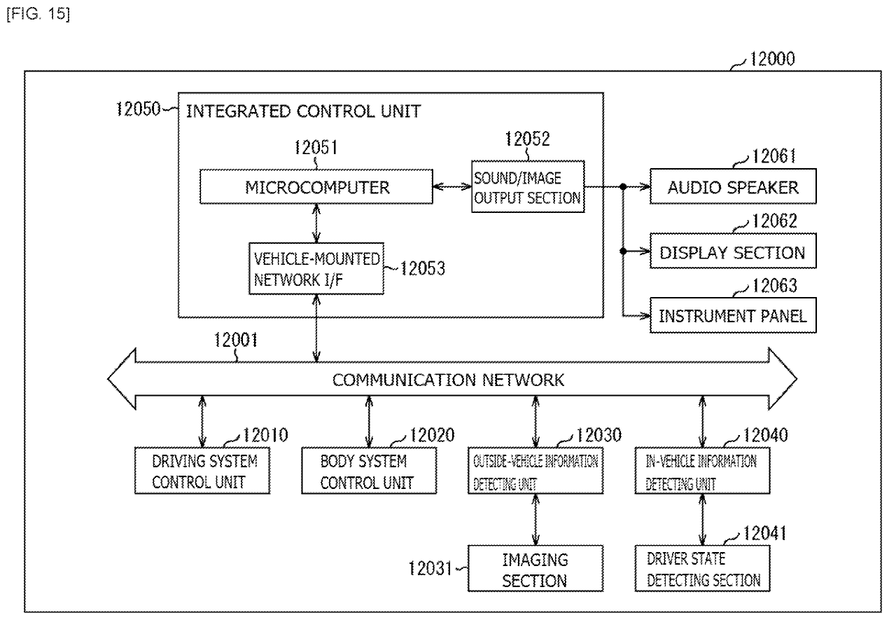

FIG. 15 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 15, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automatic driving, which makes the vehicle to travel autonomously without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 15, an audio speaker 12061, a display section 12062, and an instrument panel 12063 are illustrated as the output device. The display section 12062 may, for example, include at least one of an on-board display and a head-up display.

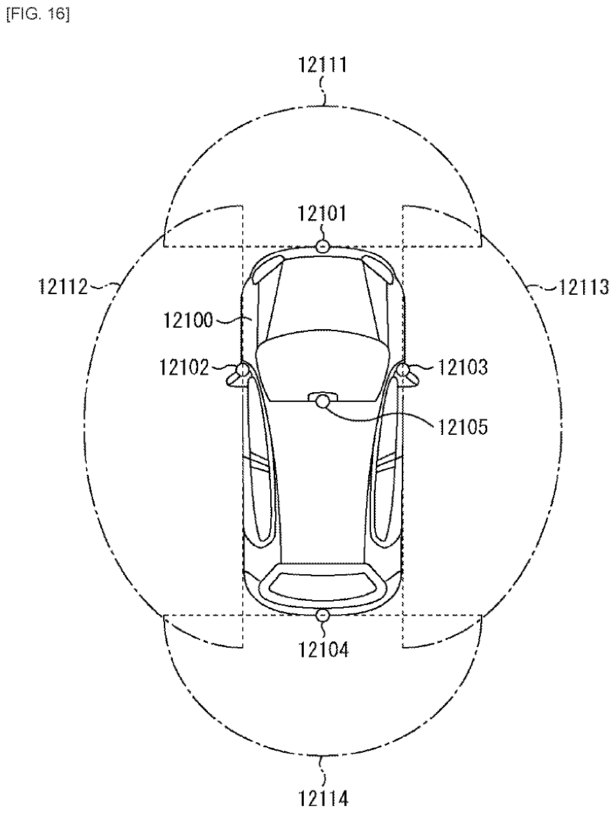

FIG. 16 is a diagram depicting an example of the installation position of the imaging section 12031.

In FIG. 16, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 16 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element including pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automatic driving that makes the vehicle travel autonomously without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The description has been given above with reference to the embodiment and Modification Examples 1 to 3; however, the contents of the present disclosure are not limited to the foregoing embodiment and the like, and may be modified in a variety of ways. For example, in the foregoing embodiment and the like, an example in which electrons are used as the signal electric charge has been described; however, holes may be used as the signal electric charge.

Further, in the foregoing embodiment and the like, the semiconductor substrate 11 including the p-well 21 has been described as an example; however, in the semiconductor substrate 11, an n-well in which an impurity concentration is controlled to be n-type may be formed in place of the p-well 21. Furthermore, in the foregoing embodiment and the like, an example in which a negative potential is applied to the anode has been described; however, as long as under a condition that avalanche multiplication occurs by application of a reverse bias to between the anode and the cathode, the respective potentials are not limited.

Further, the effects described in the foregoing embodiment and the like are merely exemplary, and may be any other effects or may further include any other effects.

It is to be noted that the present disclosure may have the following configurations. According to the present disclosure having the following configurations, in the pixel array section of the semiconductor substrate in which the plurality of pixels is arranged in an array, the first pixel separation section extending from one surface toward the other surface between the pixels has the bottom provided in the semiconductor substrate. This allows for sharing of the semiconductor substrate on side of the other surface. As a result, for example, it becomes unnecessary to provide the anode for each pixel, thus making it possible for the anode to be commonly used among the plurality of pixels. Accordingly, it is possible to reduce the pixel size.

(1)

A sensor chip including:

a semiconductor substrate including a pixel array section in which a plurality of pixels is arranged in an array;

a light receiving element provided in the semiconductor substrate for each of the pixels and including a multiplier region in which avalanche multiplication of carriers is caused by a high electric field region; and

a first pixel separation section provided between the pixels, the first pixel separation section extending from one surface of the semiconductor substrate toward another surface thereof opposed to the one surface, and having a bottom in the semiconductor substrate.

(2)

The sensor chip according to (1), in which

the semiconductor substrate includes a well for each of the pixels, and

the well is shared by the plurality of pixels on side of the other surface of the semiconductor substrate.

(3)

The sensor chip according to (1) or (2), further including a light reflection section stacked on side of the one surface of the semiconductor substrate and provided to cover at least a portion of the high electric field region.

(4)

The sensor chip according to any one of (1) to (3), in which the first pixel separation section includes a first light-blocking film including an electrically-conductive material having a light-blocking property, and an insulating film covering a surface of the first light-blocking film in the semiconductor substrate.

(5)

The sensor chip according to any one of (2) to (4), in which the well is electrically coupled to an anode in a peripheral section provided around the pixel array section.

(6)

The sensor chip according to (5), in which the anode is commonly used by the plurality of pixels.

(7)

The sensor chip according to any one of (1) to (6), in which the semiconductor substrate further includes a second pixel separation section provided between the pixels and extending from the other surface toward the one surface.

(8)

The sensor chip according to (7), in which the second pixel separation section includes an oxide film.

(9)

The sensor chip according to (7) or (8), in which a bottom of the second pixel separation section is in contact with the bottom of the first pixel separation section in the semiconductor substrate.

(10)

The sensor chip according to any one of (7) to (9), in which the second pixel separation section has an opening at an intersection point of adjacent ones of the plurality of pixels.

(11)

The sensor chip according to (7) or (8), in which the first pixel separation section and the second pixel separation section have a gap between their respective bottoms.

(12)

The sensor chip according to any one of (1) to (11), further including a second light-blocking film between the pixels on the other surface of the semiconductor substrate.

(13)

The sensor chip according to (12), in which the second light-blocking film is electrically coupled to the semiconductor substrate in the peripheral section.

(14)

The sensor chip according to any one of (7) to (13), further including a second light-blocking film between the pixels on the other surface of the semiconductor substrate,

in which a portion of the second light-blocking film extends in the second pixel separation section.

(15)

The sensor chip according to any one of (4) to (14), further including a voltage application section,

in which a voltage is applied from the voltage application section to the first light-blocking film.

(16)

The sensor chip according to any one of (1) to (15), in which

the semiconductor substrate includes a peripheral section around the pixel array section, and

the pixel array section and the peripheral section are electrically separated from each other by an insulating film.

(17)

The sensor chip according to any one of (1) to (16), further including an on-chip lens stacked on side of the other surface of the semiconductor substrate.

(18)

A distance measurement device including an optical system, a sensor chip, and a signal processing circuit that calculates a distance to a measurement target object from an output signal of the sensor chip,

in which the sensor chip includes:

a semiconductor substrate including a pixel array section in which a plurality of pixels is arranged in an array;

a light receiving element provided in the semiconductor substrate for each of the pixels and including a multiplier region in which avalanche multiplication of carriers is caused by a high electric field region; and

a first pixel separation section provided between the pixels, the first pixel separation section extending from one surface of the semiconductor substrate toward another surface thereof opposed to the one surface, and having a bottom in the semiconductor substrate.

This application claims priority from Japanese Patent Application No. 2019-065375 filed with the Japan Patent Office on Mar. 29, 2019, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A sensor chip comprising:
a semiconductor substrate including a pixel array section in which a plurality of pixels is arranged in an array;
a light receiving element provided in the semiconductor substrate for each of the pixels and including a multiplier region in which avalanche multiplication of carriers is caused by a high electric field region; and
a first pixel separation section provided between the pixels, the first pixel separation section extending from one surface of the semiconductor substrate toward another surface thereof opposed to the one surface, and having a bottom in the semiconductor substrate.

2. The sensor chip according to claim 1, wherein
the semiconductor substrate includes a well for each of the pixels, and
the well is shared by the plurality of pixels on side of the other surface of the semiconductor substrate.

3. The sensor chip according to claim 1, further comprising a light reflection section stacked on side of the one surface of the semiconductor substrate and provided to cover at least a portion of the high electric field region.

4. The sensor chip according to claim 1, wherein the first pixel separation section includes a first light-blocking film including an electrically-conductive material having a light-blocking property, and an insulating film covering a surface of the first light-blocking film in the semiconductor substrate.

5. The sensor chip according to claim 2, wherein the well is electrically coupled to an anode in a peripheral section provided around the pixel array section.

6. The sensor chip according to claim 5, wherein the anode is commonly used by the plurality of pixels.

7. The sensor chip according to claim 1, wherein the semiconductor substrate further includes a second pixel separation section provided between the pixels and extending from the other surface toward the one surface.

8. The sensor chip according to claim 7, wherein the second pixel separation section includes an oxide film.

9. The sensor chip according to claim 7, wherein a bottom of the second pixel separation section is in contact with the bottom of the first pixel separation section in the semiconductor substrate.

10. The sensor chip according to claim 7, wherein the second pixel separation section has an opening at an intersection point of adjacent ones of the plurality of pixels.

11. The sensor chip according to claim 7, wherein the first pixel separation section and the second pixel separation section have a gap between their respective bottoms.

12. The sensor chip according to claim 1, further comprising a second light-blocking film between the pixels on the other surface of the semiconductor substrate.

13. The sensor chip according to claim 12, wherein the second light-blocking film is electrically coupled to the semiconductor substrate in a peripheral section provided around the pixel array section.

14. The sensor chip according to claim 7, further comprising a second light-blocking film between the pixels on the other surface of the semiconductor substrate,
wherein a portion of the second light-blocking film extends in the second pixel separation section.

15. The sensor chip according to claim 4, further comprising a voltage application section,
wherein a voltage is applied from the voltage application section to the first light-blocking film.

16. The sensor chip according to claim 1, wherein
the semiconductor substrate includes a peripheral section around the pixel array section, and
the pixel array section and the peripheral section are electrically separated from each other by an insulating film.

17. The sensor chip according to claim 1, further comprising an on-chip lens stacked on side of the other surface of the semiconductor substrate.

18. A distance measurement device comprising an optical system, a sensor chip, and a signal processing circuit that calculates a distance to a measurement target object from an output signal of the sensor chip,
wherein the sensor chip includes:
a semiconductor substrate including a pixel array section in which a plurality of pixels is arranged in an array;
a light receiving element provided in the semiconductor substrate for each of the pixels and including a multiplier region in which avalanche multiplication of carriers is caused by a high electric field region; and
a first pixel separation section provided between the pixels, the first pixel separation section extending from one surface of the semiconductor substrate toward another surface thereof opposed to the one surface, and having a bottom in the semiconductor substrate.
